(19) United States
(12) Patent Application Publication
(10) Pub. No.: US 2004/0035697 A1
(43) Pub. Date: Feb. 26, 2004

(54) Cathodic sputtering metal backing plate

(76) Inventors: David I. May, Ashville, OH (US); Ron G. Snelly, Obetz, OH (US); Gretchen M. Wilk, Grove City, OH (US)

Correspondence Address: THOMAS S. BAKER, JR., 1371 WEST 3RD AVENUE, COLUMBUS, OH, 43212, US

(21) Appl. No.: 10/225,602

(22) Filed: Aug. 22, 2002

(51) Int. Cl. C23C 14/32

(52) U.S. Cl. 204/298.12

(57) ABSTRACT

Metal sputtering apparatus is provided with a cathodic backing plate element having at least one sputtering metal cavity that contains a sputtering metal and that has a peripheral undercut that enhances the retention of the contained sputtering metal in the sputtering metal cavity.

### CROSS-REFERENCES

None.

### FIELD OF THE INVENTION

This invention relates generally to the cathodic sputtering of cast metallic alloys, and specifically pertains to an improved backing plate for use with conventional high-power density cathodic metal sputtering equipment.

### BACKGROUND OF THE INVENTION

The use of known or conventional backing plates for the containment of metallic sputtering alloys often results in separation of the contained cast alloy from the backing plate, cracking of the low melting and/or low thermally conductive sputtering alloy during high power density sputtering, meltdown of the alloy during sputtering processing, or shrinking of the backing plate during the casting of additional sputtering alloy into the alloy-containing cavity of the backing plate.

Accordingly a principal objective of the present invention is to provide an improved target for high power use in magnetically enhanced cathodic sputtering of low melting point alloys and metals.

Another objective of the present invention is to provide a backing plate construction for use in high power density metal sputtering equipment that overcomes the deficiencies noted above with respect to known conventional backing plates for such equipment.

Other objects and advantages of the present invention will become apparent during consideration of the detailed descriptions, drawings, and claims which follow.

### SUMMARY OF THE INVENTION

The present invention involves use of a machinable metallic backing plate (e.g., copper, titanium, or the like) which is provided with one or more cavities for containing cast metallic sputtering material, each such cavity having being provided with one or more cavity undercuts around its plan periphery.

### BRIEF DESCRIPTION OF THE DRAWINGS

FIG. 1 is a simplified schematic elevation end-view of conventional metallic sputtering equipment incorporating the backing plate of the present invention therein;

FIG. 2 is a plan view of the backing plate component of the FIG. 1 apparatus; and

FIG. 3 is a schematic cross-section view of the backing plate component of FIG. 2 but with a body of solidified metallic sputtering alloy cast into the alloy-containing cavities thereof.

### DETAILED DESCRIPTION

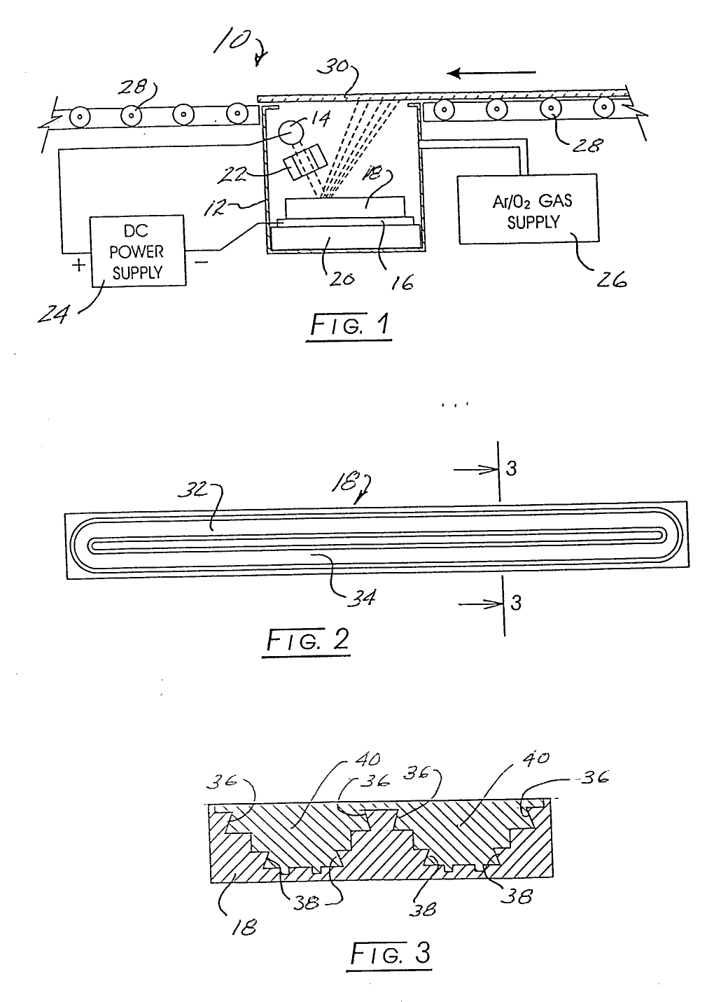

FIG. 1 schematically illustrates sputtering apparatus 10 comprised of a partially open chamber 12 that contains anode 14, cathodic support plate 16 having the readily-removable backing plate 18 of the present invention mounted thereon, an electrically non-conductive base member 20, and an electron beam focusing coil 22. The FIG. 1 equipment also includes a direct current power supply 24 connected to the system anode and to the cathodic support plate as shown, and a gas supply 26 of combined argon and oxygen supplying those gases to the interior of chamber 12. Equipment 10, which represents a system for coating an under surface of a transparent glass sheet 30 as it is moved along conveyor 28, also includes a supply of a cast metal such as zinc, tin, or zinctin alloy contained in the containment cavity of backing plate element 18.

FIG. 2 illustrates a preferred embodiment of backing plate 18 which is shown in its normal position of being mounted in an electricity-conducting manner upon cathodic support plate 16. The FIG. 2 illustration is based on an actual embodiment of our invention wherein such had overall dimensions of approximately 62 to 144 inches length, approximately 13.13 inches width, and approximately 1.25 inches depth. Backing plate element 18 is preferably comprised of copper, titanium, or any other machinable and electrically-conductive metal, and includes a pair of sub-cavities 32, 34 which are inter-connected at each end of element 18 to form an overall closed-loop cavity having the configuration of a flattened circle. Each sub-cavity has machined peripheral outer and inner upper undercuts 36 and machined peripheral outer and inner lower undercuts 38. See FIG. 3. Also, in FIG. 3 we show the sub-cavities as being filled with a cast sputtering metal 40 such as zinc, tin, or a zinc-tin alloy. Also, if desired but not shown, the aforesaid peripheral undercuts may be replaced with an equivalent series of small, spaced-apart blind holes added to the inner surfaces of cavities 32, 34 to enhance the adherence of the cast sputtering metal to the interior surfaces of back plate element 18.

In the basic sputtering process a direct-current potential applied between anode 14 and cathodic and the cathodic support plate/backing plate combination 16 causes the bombardment of the cast sputtering metal 40 with argon/oxygen ions and the melting and emitting of cast sputtering metal atoms into chamber 12 for deposit on the underside of glass sheet 30 as it is conveyed past the top opening of chamber 12.

Various changes to the disclosed shape, proportioning, size, and materials of construction may be made without departing from the meaning, scope, or intent of the claims which follow.

We claim our invention as follows:

1. In metal sputtering apparatus having a direct current power supply and an anode and a cathode each electrically-connected to the direct current power supply, in combination;
an electrically-conducting backing plate element electrically connected to the metal sputtering apparatus cathode;
at least one sputtering metal cavity in an upper surface of said electrically-conducting backing plate element; and
cast sputtering metal contained in said sputtering metal cavity,
each said sputtering metal filled cavity having at least one peripheral undercut enhancing the retention of said cast sputtering metal within said cavity.

2. The invention defined by claim 1, and wherein each said sputtering metal cavity has an upper peripheral undercut and a lower peripheral undercut.

3. The invention defined by claim 1, and wherein each said sputtering metal cavity is comprised of a series of linearly spaced-apart blind holes.

4. An electrically-conducting backing plate element for use in a metal sputtering apparatus and having at least one sputtering metal cavity in its upper surface for containment of a cast sputtering metal, each said sputtering metal cavity having at least one peripheral undercut enhancing the retention of the cast sputtering metal within said cavity.

5. The invention defined by claim 4, and wherein each said sputtering metal cavity has an upper peripheral undercut and a lower peripheral undercut.

6. The invention defined by claim 4, and wherein each said peripheral under cut is comprised of a series of linearly spaced-apart blind holes.

7. An electrically-conducting backing plate element for use in a metal sputtering apparatus and having at least one sputtering metal cavity in its upper surface filled with a cast sputtering metal, each said sputtering metal cavity having at least one peripheral undercut enhancing the retention of the cast sputtering metal within said cavity.
